(19) United States
(12) Patent Application Publication
(10) Pub. No.: US 2018/0282866 A1
(43) Pub. Date: Oct. 4, 2018

(54) RUTHENIUM PRECURSOR, PREPARATION METHOD THEREFOR AND METHOD FOR FORMING THIN FILM USING SAME

(71) Applicant: KOREA RESEARCH INSTITUTE OF CHEMICAL TECHNOLOGY, Daejeon (KR)

(72) Inventors: Bo-Keun PARK, Gangwon-do (KR); Taek-Mo CHUNG, Daejeon (KR); Chang-Gyoun KIM, Daejeon (KR); Dong-Ju JEON, Daejeon (KR); Eun-Ae JUNG, Daegu (KR)

(21) Appl. No.: 15/763,378

(22) PCT Filed: May 2, 2014
(86) PCT No.: PCT/KR2014/003957

§ 371 Date: Mar. 26, 2018

(30) Foreign Application Priority Data
May 3, 2013 (KR) 10-2013-0050310

(51) Int. Cl. C23C 16/455; C23C 16/18; C07F 15/00

(52) U.S. Cl. CPC C23C 16/45553; C07F 15/0046; C23C 16/18

(57) ABSTRACT

The present invention relates to a ruthenium precursor represented by Chemical Formula 1, and the ruthenium precursor has the advantages of having improved thermal stability and volatility and not having to use oxygen when depositing a thin film, and thus is capable of forming a high-quality ruthenium thin film.

### TECHNICAL FIELD

The present invention relates to a novel ruthenium precursor, and more particularly, to a ruthenium precursor capable of having improved thermal stability and volatility and easily manufacturing a high-quality ruthenium thin film at a low temperature, a method for preparing the same, and a method of manufacturing a ruthenium thin film using the same.

### BACKGROUND ART

A ruthenium metal has excellent thermal and chemical stability, low specific resistance (r_{bulk}=7.6 mWcm), and a relatively large work function (F_{bulk}=4.71 eV). Further, the ruthenium metal has excellent adhesion with a copper metal, and ruthenium oxide (RuO₂) is also a conductive oxide having low specific electric conductivity (r_{bulk}=46 mWcm) and has excellent properties as an oxygen diffusion barrier and excellent thermal stability even at 800° C., such that the ruthenium metal has been spotlighted as a capacitor electrode material among next-generation semiconductor materials such as a ferroelectric random access memory (FeRAM) and dynamic random access memory (DRAM). Ruthenium as described above has physical properties suitable for being used as a latent gate electrode material for a complementary metal-oxide semiconductor (CMOS) transistor, such as a high melting point, low specific resistance, high oxidation resistance, and a suitable function of action. Actually, specific resistance of ruthenium is lower than those of iridium and platinum, such that ruthenium may be more easily used in a dry etching process. Additionally, since ruthenium oxide (RuO₂) may have high conductivity and be formed by diffusion of oxygen generated from a ferroelectric film such as lead-zirconate-titanate (PZT), strontium bismuth tantalate (SBT), or bismuth lanthanum titanate (BLT), ruthenium oxide (RuO₂) may be electrically stably used as compared to other metal oxides known to have an insulating property, and strontium ruthenium oxide (SRO, SrRuO₃) may also be used as a material of a next-generation semiconductor.

As a ruthenium precursor known in the art, a ruthenium precursor containing nitrogen and two ligands different from each other was disclosed in U.S. Patent Application Publication No. 2009-0028745, and a ruthenium precursor including a benzene ring and cyclic or acyclic alkene compound was disclosed in Korean Patent Laid-Open Publication No. 10-2010-0060482.

However, existing divalent ruthenium precursors have a problem in that oxygen should be used as a reaction gas at the time of performing an atomic layer deposition (ALD) process. Therefore, a ruthenium precursor capable of having excellent thermal stability, chemical reactivity, and volatility, and a high deposition rate of a ruthenium metal without using oxygen should be developed.

### DISCLOSURE

### Technical Problem

An object of the present invention is to provide a novel ruthenium precursor capable of having improved thermal stability and volatility and easily manufacturing a high-quality ruthenium thin film at a low temperature.

### Technical Solution

In one general aspect, there is provided a ruthenium precursor represented by the following Chemical Formula 1.

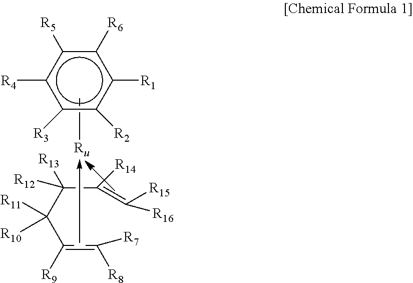

(In Chemical Formula 1, R₁ to R₁₆ are each independently H or a linear or branched (C1-C4) alkyl group.)

In another general aspect, there is provided a method for preparing the ruthenium precursor represented by Chemical Formula 1 described above, the method including reacting: a compound represented by the following Chemical Formula 2 and a compound represented by the following Chemical Formula 3 with each other.

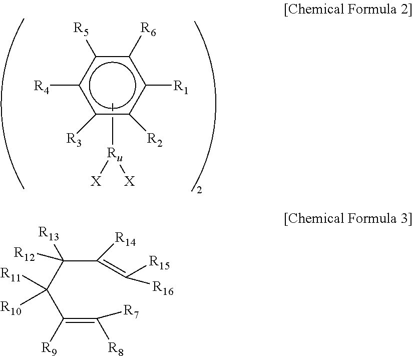

(In Chemical Formulas 2 and 3, X is Cl, Br, or I, and R₁ to R₁₆ are each independently H or a linear or branched (C1-C4) alkyl group.)

In another general aspect, there is provided a method for growing a ruthenium thin film using the ruthenium precursor represented by Chemical Formula 1 described above.

### Advantageous Effects

Since a ruthenium precursor according to the present invention has advantages in that thermal stability and volatility are improved and since the ruthenium precursor is a zero-valent compound, there is no need to use oxygen at the time of depositing a thin film, a high-quality ruthenium thin film may be easily manufactured using the ruthenium precursor.

### DESCRIPTION OF DRAWINGS

FIG. 1 illustrates a proton nuclear magnetic resonance (¹H NMR) spectrum of Example 1.

FIG. 2 illustrates thermo-gravimetric analysis (TGA) data of Example 1.

FIG. 3 illustrates a proton nuclear magnetic resonance (¹H NMR) spectrum of Example 2.

FIG. 4 illustrates thermo-gravimetric analysis (TGA) data of Example 2.

### BEST MODE

The present invention relates to a ruthenium precursor represented by the following Chemical Formula 1.

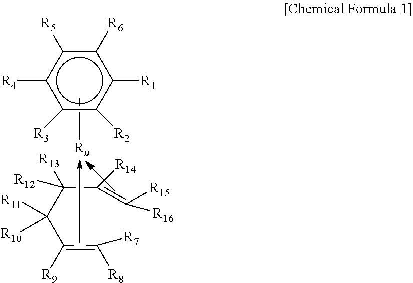

(In Chemical Formula 1, R₁ to R₁₆ are each independently H or a linear or branched (C1-C4) alkyl group.)

In Chemical Formula 1, it is preferable that R₁ to R₁₆ are each independently selected from H, CH₃, C₂H₅, CH(CH₃)₂, and C(CH₃)₃.

The ruthenium precursor represented by the following Chemical Formula 1 may be prepared by reacting a compound represented by the following Chemical Formula 2 and a compound represented by the following Chemical Formula 3 as starting materials with each other in 2-propanol as a solvent to induce a substitution reaction.

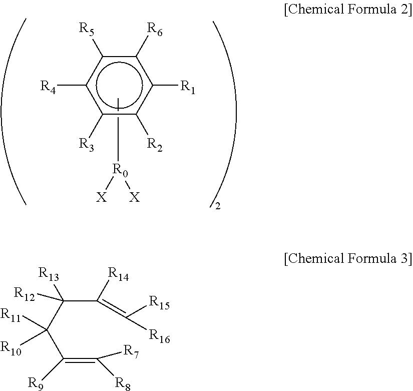

(In Chemical Formulas 2 and 3, X is Cl, Br, or I, and R₁ to R₁₆ are each independently H or a linear or branched (C1-C4) alkyl group.)

The solvent is not particularly limited, but 2-propanol may be preferably used.

A specific reaction process for preparing the ruthenium precursor according to the present invention may be represented by the following Reaction Formula 1.

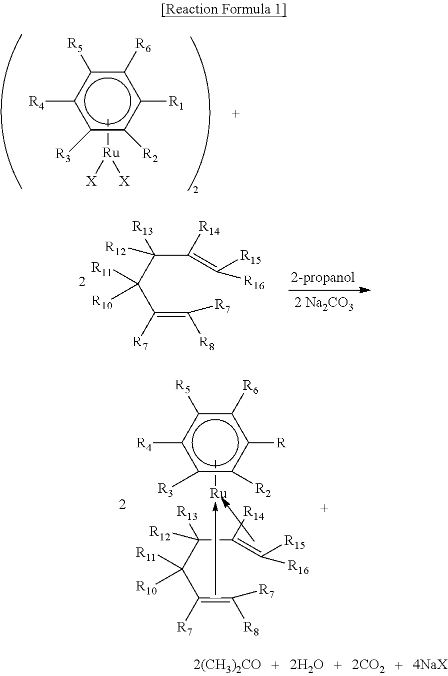

(In Reaction Formula 1, X is Cl, Br, or I, and R₁ to R₁₆ are each independently H or a linear or branched (C1-C4) alkyl group.)

According to Reaction Formula 1, after the substitution reaction is carried out in 2-propanol as the solvent at room temperature for 15 to 24 hours, the mixture is filtered, and the solvent is removed under reduced pressure, thereby obtaining a liquid compound. By-products may be formed during the reaction represented by Reaction Formula 1, and a novel ruthenium precursor with high purity may be obtained by removing these by-products using a sublimation method or a re-crystallization method.

In the reaction, reactants are used at stoichiometric ratios.

The novel ruthenium precursor represented by Chemical Formula 1, which is a stable liquid at room temperature, is thermally stable and has excellent volatility. The novel ruthenium precursor according to the present invention may be preferably used in a process using a chemical vapor deposition (CVD) method or an atomic layer deposition (ALD) method.

### DETAILED DESCRIPTION OF EXAMPLES

Hereinafter, the present invention will be understood and appreciated more fully from the Examples, and the Examples are for illustrating the present invention and not for limiting the present invention defined by the accompanying claims.

### Example

Synthesis of Ruthenium Precursor Material

### Example 1: Preparation of (Benzene) (Hexadiene)Ru(0)

After [Ru(benzene)Cl₂]₂ (20 g, 0.04 mol, 1 eq) and 2-propanol (100 mL) were put into a three-neck flask, sodium carbonate (20 g) was added thereto, and then the mixture was stirred for 4 hours. After 1,5-hexadiene (13.13 g, 0.16 mol, 4 eq) was added thereto, the mixture was refluxed for 15 hours. After obtaining a viscous dark brown solution by removing the solvent and volatile by-products under reduced pressure from a solution obtained by filtering the reaction product, this solution was distillated under reduced pressure, thereby obtaining a yellow solution (benzene) (hexadiene)Ru(0) (yield: 18 g, 90%).

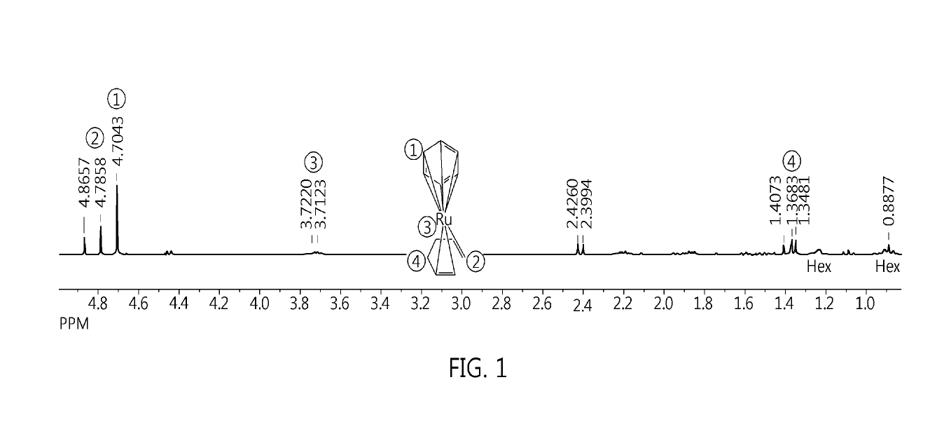

A proton nuclear magnetic resonance (¹H NMR) spectrum of the obtained compound is illustrated in FIG. 1.

¹H NMR (C₆D₆, 300.13 MHz): 1.34 (d, 4H), 3.72 (m, 2H), 4.70 (s, 6H), 4.78 (s, 2H), 4.86 (s, 2H)

EA: calcd. (found) C₁₂H₁₆Ru:C, 55.15 (56.12); H, 6.17 (5.96);

### Example 2: Preparation of (Cymene) (Hexadiene)Ru(0)

After [Ru(cymene)Cl₂]₂ (20 g, 0.03 mol, 1 eq) and 2-propanol (120 mL) were put into a three-neck flask, sodium carbonate (20 g) was added thereto, and then the mixture was stirred for 4 hours. After 1,5-hexadiene (10.73 g, 0.13 mol, 4 eq) was added thereto, the mixture was refluxed for 15 hours. A viscous dark red brown solution was obtained by removing the solvent and volatile by-products under reduced pressure from a solution obtained by filtering the reaction product. This solution was distilled under reduced pressure, thereby obtaining a yellow solution (cymene) (hexadiene)Ru(0) (yield: 16 g, 80%).

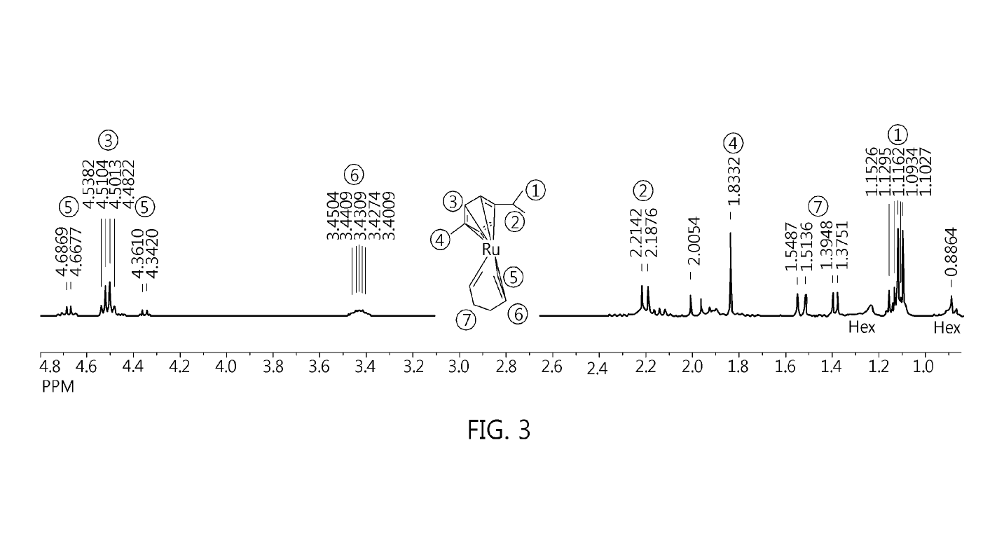

A proton nuclear magnetic resonance (¹H NMR) spectrum of the obtained compound is illustrated in FIG. 3.

¹H NMR (C₆D₆, 300.13 MHz): 1.12 (d, 6H), 1.37 (d, 2H), 1.51 (d, 2H), 1.83 (s, 3H), 2.00 (m, 1H), 3.45 (m, 2H), 4.34 (q, 2H), 4.50 (q, 4H), 4.66 (q, 2H).

EA: calcd. (found) C₁₆H₂₄Ru:C, 60.54 (61.88); H, 7.62 (7.85);

Thermal Analysis of Ruthenium Precursor

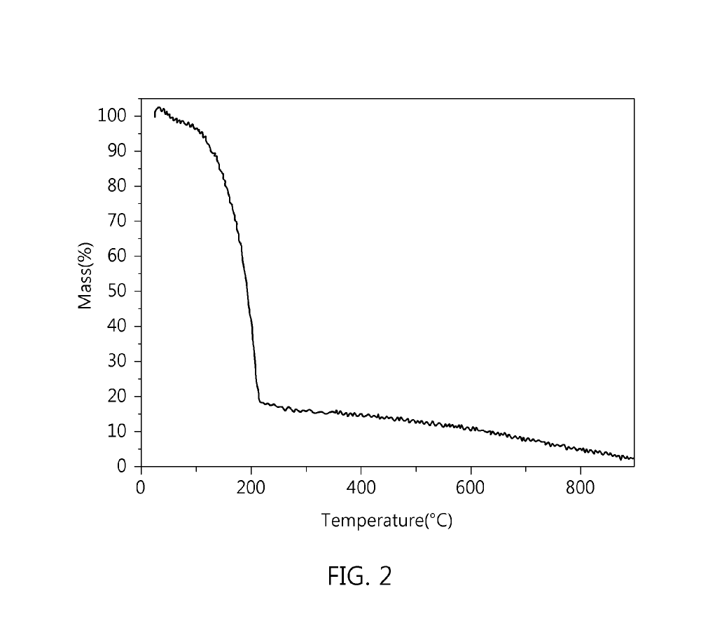

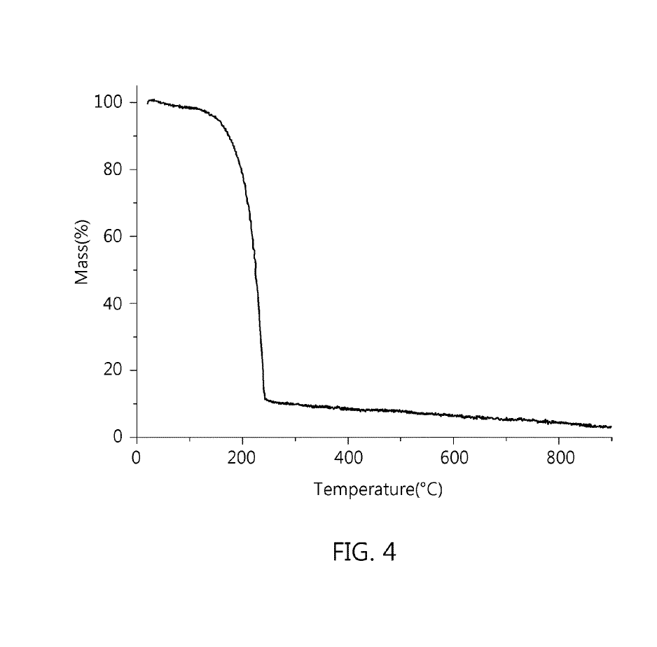

In order to measure thermal stability, volatility, and decomposition temperatures of the ruthenium precursor compounds synthesized in Examples 1 and 2, while each of the ruthenium precursor compounds synthesized in Examples 1 and 2 was heated to 900° C. at a rate of 10° C./min, argon gas was injected thereto at a rate of 1.5 bar/min. Thermo-gravimetric analysis (TGA) graphs of the precursors are illustrated in FIGS. 2 and 4, respectively.

In the precursor in Example 1, it was observed that mass was decreased in the vicinity of 100 to 110° C., and the mass was decreased by 82% or more at 210° C. as illustrated in FIG. 2. From this result, it was confirmed that T_{1/2} was 190° C. in the TGA graph.

In the precursor in Example 2, it was observed that mass was decreased in the vicinity of 130° C., and the mass was decreased by 90% or more at 240° C. as illustrated in FIG. 4. From this result, it was confirmed that T_{1/2} was 220° C. in the TGA graph.

1. A ruthenium precursor represented by the following Chemical Formula 1: 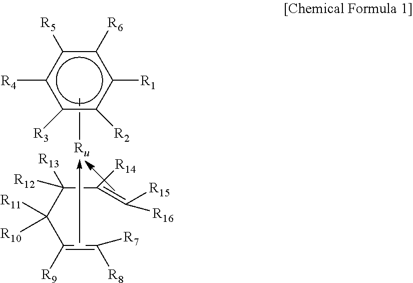
(in Chemical Formula 1, R₁ to R₁₆ are each independently H or a linear or branched (C1-C4) alkyl group).

2. The ruthenium precursor of claim 1, wherein R₁ to R₁₆ are each independently selected from H, CH₃, C₂H₅, CH(CH₃)₂, and C(CH₃)₃.

3. A method for preparing the ruthenium precursor of claim 1, represented by Chemical Formula 1, the method comprising: reacting a compound represented by the following Chemical Formula 2 and a compound represented by the following Chemical Formula 3 with each other: 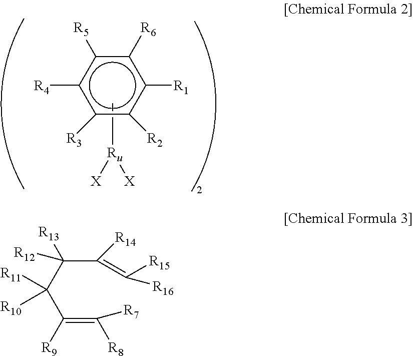
(in Chemical Formulas 2 and 3, X is Cl, Br, or I, and R₁ to R₁₆ are each independently H or a linear or branched (C1-C4) alkyl group).

4. A method for growing a ruthenium thin film using the ruthenium precursor of claim 1.

5. The method for growing a ruthenium thin film of claim 4, wherein a thin film growth process is performed by a chemical vapor deposition (CVD) method or an atomic layer deposition (ALD) method.
